(19) United States
(12) Patent Application Publication
(10) Pub. No.: US 2024/0373561 A1
(43) Pub. Date: Nov. 7, 2024

(54) SUBSTRATE HAVING ELECTRONIC COMPONENT MOUNTED IN A CAVITY OF A CORE USING A PLUGGING INK AND METHOD FOR MAKING THE SUBSTRATE

(71) Applicant: QUALCOMM Incorporated, San Diego, CA (US)

(72) Inventors: Jung Won PARK, Gumi (KR); Kuiwon KANG, San Diego, CA (US); Seongryul CHOI, Seongnam (KR)

(21) Appl. No.: 18/310,324

(22) Filed: May 1, 2023

(51) Int. Cl. H05K 1/18; H05K 3/28

(52) U.S. Cl. CPC H05K 1/186; H05K 3/284; H05K 1/115; H05K 2201/10015; H05K 2203/0156

(57) ABSTRACT

In an aspect, an electronic device is disclosed that includes a substrate comprising a core having an upper planar surface and a lower planar surface, wherein the core includes a cavity extending between the upper planar surface of the core and the lower planar surface of the core; an electronic component at least partially disposed in the cavity, wherein the electronic component is at least partially surrounded in the cavity by a cured plugging ink, the electronic component including an upper planar surface having one or more electronic component terminals; and an upper metallization structure configured to provide one or more conductive paths from the one or more electronic component terminals to one or more upper metal terminals of the upper metallization structure.

### FIELD OF DISCLOSURE

The present disclosure generally relates to a substrate, and more particularly, to a substrate having an embedded electronic component mounted in a core of the substrate.

### BACKGROUND

Integrated circuit (IC) technology has achieved great strides in advancing computing power through miniaturization of electrical components. An IC may be implemented in the form of an IC chip that has a set of circuits integrated thereon. In some implementations, one or more IC chips can be physically carried and protected by an IC package, where various power and signal nodes of the one or more IC chips can be electrically coupled to respective conductive terminals of the IC package via electrical paths formed in a package substrate of the IC package. Various packaging technologies can be found in many electronic devices, including processors, servers, radio frequency (RF) integrated circuits, etc. Advanced packaging and processing techniques can be used to implement complex devices, such as multi-electronic component devices and system on a chip (SOC) devices, which may include multiple function blocks, with each function block designed to perform a specific function, such as, for example, a microprocessor function, a graphics processing unit (GPU) function, a communications function (e.g., Wi-Fi, Bluetooth, and other communications), and the like.

In some implementations, embedded passive devices, such as deep trench capacitors, have been incorporated in IC packaging for performance improvement and package size reduction. One factor driving the use of such embedded passive devices is the desire to obtain small form factor products with equivalent or better electrical performance than their larger passive device counterparts. Depending on the size and/or thickness of the package substrate and the size and/or the process node of the IC Chip carried thereon, the process for embedding a passive device in a package substrate in one packaging task may not be suitable for another packaging task.

Accordingly, there is a need for improved methods for embedding an electrical component in a substrate, such as a package substrate, which may be suitable for a broader variety of packaging tasks.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an electronic device includes a substrate comprising a core having an upper planar surface and a lower planar surface, wherein the core includes a cavity extending between the upper planar surface of the core and the lower planar surface of the core; an electronic component at least partially disposed in the cavity, wherein the electronic component is at least partially surrounded in the cavity by a cured plugging ink, the electronic component including an upper planar surface having one or more electronic component terminals; and an upper metallization structure configured to provide one or more conductive paths from the one or more electronic component terminals to one or more upper metal terminals of the upper metallization structure.

In an aspect, a substrate includes a core having an upper planar surface and a lower planar surface, wherein the core includes a cavity extending between the upper planar surface of the core and the lower planar surface of the core; an electronic component at least partially disposed in the cavity, wherein the electronic component is at least partially surrounded in the cavity by a cured plugging ink, the electronic component including an upper planar surface having one or more electronic component terminals; and an upper metallization structure configured to provide one or more conductive paths from the one or more electronic component terminals to one or more upper metal terminals of the upper metallization structure.

In an aspect, a method for fabricating a substrate includes forming a cavity in a core having a first planar surface and a second planar surface, wherein the cavity extends between the first planar surface and the second planar surface of the core; embedding an electronic component at least partially in the cavity, wherein the electronic component is at least partially surrounded in the cavity by a cured plugging ink, the electronic component including a planar surface having one or more electronic component terminals; and forming a metallization structure configured to provide one or more conductive paths from the one or more electronic component terminals to one or more metal terminals of the metallization structure.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1 is a cross-sectional view of an example substrate with an embedded electronic component, according to aspects of the disclosure.

FIG. 2 is a cross-sectional view of the example substrate of FIG. 1 showing the propagation of voids in a dielectric material and resulting defects, according to aspects of the disclosure.

FIG. 3 is a cross-sectional view of an example deep trench capacitor, according to aspects of the disclosure.

FIG. 4 is a cross-sectional view of an example substrate, according to aspects of the disclosure.

FIGS. 5A through 5I illustrate example steps undertaken in fabricating an example substrate, according to aspects of the disclosure.

FIGS. 6A through 6H illustrate example steps undertaken in fabricating an example substrate, according to aspects of the disclosure.

FIG. 7 is a flowchart showing an example method for fabricating a substrate, according to aspects of the disclosure.

FIG. 8 illustrates a profile view of a package that includes a surface mount substrate, an integrated device and an integrated passive device, according to aspects of the disclosure.

FIG. 9 illustrates an exemplary flow diagram of a method for fabricating a package that includes a substrate, an integrated device and an integrated passive device.

FIG. 10 illustrates various electronic devices that may integrate an electronic component, an electronic circuit, an integrated device, an integrated passive device, a passive component, a package, and/or a device package described herein.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including.” when used herein, specify the presence of stated features, integers, steps, operations, elements, and/or components, but do not preclude the presence or addition of one or more other features, integers, steps, operations, elements, components, and/or groups thereof.

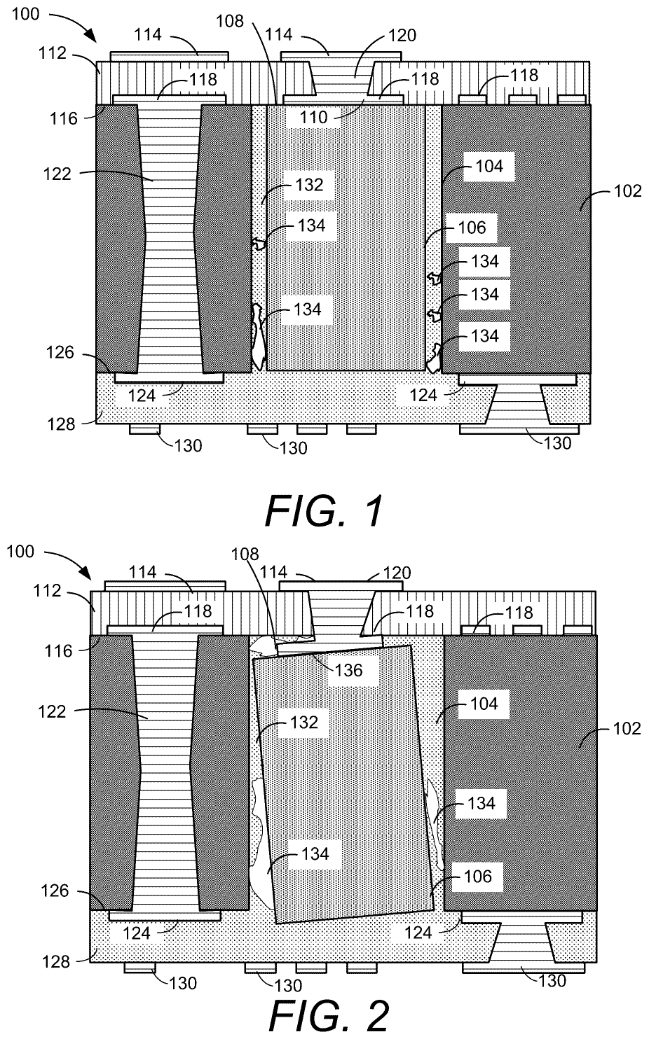

FIG. 1 is a cross-sectional view of an example substrate 100 with an embedded electronic component, according to aspects of the disclosure. In this example, the substrate 100 includes a core 102 having a cavity 104 that extends entirely through the core 102. An electronic component 106 is disposed within the cavity 104. The electronic component 106 has an upper planar surface 108 with one or more electronic component terminals 110 that provide an electrical connection to a device (e.g., deep trench capacitor) configured by the electronic component 106.

In accordance with various aspects of the disclosure, the substrates described herein (e.g., substrate 100) that include a core and an embedded electronic component are directed to package substrates. A package substrate is the part of an integrated circuit package that gives the board its mechanical strength and allows it to connect with external devices. Such package substrates are to be distinguished from other substrates, such as the substrates that may be included in the embedded electronic component itself, dies including substrates (e.g., silicon substrates or other similar electronic devices).

The substrate 100 further includes a plurality of dielectric layers 112 and patterned metallization layers 114 overlying an upper planar surface 116 of the core 102 (only one such dielectric layer and corresponding patterned metal layer overlying the upper planar surface 116 are shown in FIG. 1). A patterned metallization layer 118 including a via structure 120 is disposed at the upper planar surface 116 of the core 102 to provide an electrical connection between the one or more electronic component terminals 110 and the patterned metallization layers 114.

In this example, one or more vias 122 extend through the core 102 and connect the patterned metallization layer 118 at the upper planar surface 116 of the core 102 with a further patterned metallization layer 124 at a lower surface 126 of the core 102. A further plurality of dielectric layers 128 and patterned metallization layers 130 are formed over the lower surface 126 of the core 102 (only one such dielectric layer and corresponding patterned metal layer formed over the lower surface 126 are shown in FIG. 1).

In an aspect, the same dielectric material as used in forming the dielectric layers 128 may be used to fill the cavity 104. Commonly used dielectric materials include Ajinomoto Build-Up Film® (ABF), PPG® liquid resins, and the like. During the manufacture of the substrate 100, the electronic component 106 is inserted in the cavity 104 before the dielectric resin is injected to fill the regions 132 between the cavity 104 and the electronic component 106. During insertion, the electronic component 106 is carefully aligned within the cavity 104 to ensure that the one or more electronic component terminals 110 properly contact and electrically bond with the corresponding portions of the patterned metallization layer 118. Additionally, the injection of the dielectric resin in the regions 132 should be undertaken with care so as not to disturb the initial alignment of the electronic component 106 within the cavity 104. In an aspect, the dielectric resin, once cured, secures the electronic component 106 at its proper location within the cavity 104.

Current trends in substrate design are directed to applications that present unique design and manufacturing issues (e.g., need for reduced substrate warpage, a need for cavities that accommodate large electronic components, a need for larger keep-out zones, etc.). These issues may be addressed, at least in part, by employing thick cores in the design and manufacture of such substrates. For example, warpage control is more easily achieved with thick cores than with thin cores. Additionally, the need for larger cavity sizes and keep-out zones can be met by employing such thick cores. In certain scenarios, cores (e.g., both thick and thin cores) may be required to accept large, embedded electronic components in which the electronic component occupies a substantial volume of the cavity in which the electronic component is embedded.

However, substrates employing thick cores or requiring large, embedded electronic components may be difficult to manufacture using the same packaging technologies that are used in manufacturing substrates having thin cores and/or smaller embedded electronic components. With thick cores, there is a significant gap between the electronic component and the cavity resulting from the increased depth of the cavity compared to the height of the electronic component (e.g., the thick core has a thickness that is greater than the height of the die). In such thick core scenarios, it may be difficult or impossible to fill the cavity (e.g., particularly the regions between the exterior of the electronic component and the interior walls of the cavity) with the commonly used dielectric resins (e.g., Ajinomoto Build-Up Film® (ABF), PPG® liquid resins, etc.) without voids in the resulting dielectric material in which the electronic component is ultimately embedded. Similarly, when the electronic component takes up a substantial volume of the cavity, it may be difficult to adequately fill the small regions between the electronic component and the cavity with the commonly used dielectric resins without voids in the resulting dielectric material in which the electronic component is ultimately embedded.

FIG. 1 shows voids 134 in the dielectric material filling the cavity 104 that occur when the regions between the interior surfaces of the cavity 104 and the exterior surfaces of the electronic component 106 are not adequately filled with the dielectric material. In FIG. 1, the voids 134 in the dielectric material have not presented an immediate problem with the connection between the one or more electronic component terminals 110 and the patterned metallization layer 118. However, the voids 134 may propagate through the dielectric material as a result of the thermal and/or mechanical stresses that occur during use of the substrate for its intended purpose.

FIG. 2 is a cross-sectional view of the example substrate 100 showing the propagation of the voids 134 in the dielectric material and the resulting defects, according to aspects of the disclosure. For purposes of simplicity, reference numbers used in FIG. 1 have also been used to designate similar elements in FIG. 2.

In FIG. 2, the propagation of the voids 134 has allowed the electronic component 106 to shift its position within the cavity 104 resulting in a delamination of the electronic component 106 from the core 102. Such delamination may result in reduced performance and/or a complete failure of the electronic device in which the substrate 100 is incorporated.

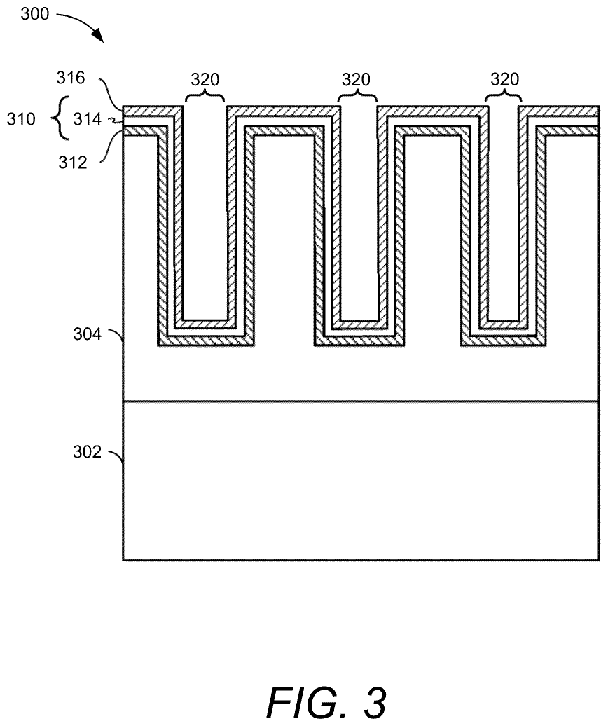

According to certain aspects of the disclosure, the electronic component may be a DTC. FIG. 3 is a cross-sectional view of an example DTC 300, according to aspects of the disclosure. In FIG. 3, a capacitor 310 is deposited in trenches 320 of an insulator 304 on a substrate 302. The capacitor 310 may include a metal layer 312, a dielectric layer 314, and a metal layer 316. The dielectric layer 314 separates the metal layer 312 from the metal layer 316. The metal layers 312, 316 form electrodes of the capacitor 310 and may be connected to terminals at, for example, a surface (see, e.g., the upper surface 108 with the electronic component terminals 110 of electronic component 106 shown in FIG. 1). In some scenarios, the capacitors are formed from an array of deep trenches in a substrate and filled with an electrical insulator (e.g., a dielectric) between layers of electrodes. In some scenarios, the capacitors are attached on the land side under in integrated circuit die shadow (land-side capacitor: LSC) or adjacent to the die on the die side (die-side capacitor: DSC).

Certain aspects of the disclosure are implemented with a recognition of the problems associated with using existing processing technologies and materials to manufacture substrates having thick cores and/or cavities that accommodate large, embedded electronic components. In accordance with certain aspects of the disclosure, the electronic component may be embedded in the cavity using a plugging ink that is dispensed within the cavity and subsequently cured to secure the electronic component within the cavity. Such plugging inks are frequently used in existing fabrication operations to fill hollow vias extending through the core of the substrate. Certain aspects of the disclosure are implemented with a recognition that such plugging inks have fluid and other material characteristics (e.g., low viscosity) that allow the plugging inks to substantially fill the regions between the interior surfaces of the cavity and the exterior surfaces of the electronic component without voids thereby providing a more robust embedding of the electronic component within the core of the substrate. In an aspect, certain prior processes dispense a fixed amount of filler material in the cavity, whereas the plugging ink of the present disclosure may be dispensed into the cavity until the cavity is filled. In accordance with certain aspects of the disclosure, and without limitation, plugging inks such as the THP-100DX1 series hole plugging ink available from Taiyo America, Inc., and the PHP900 series hole plugging ink available from San-Ei Kagaku Co., Ltd. are suitable for securing the electronic component within the cavity.

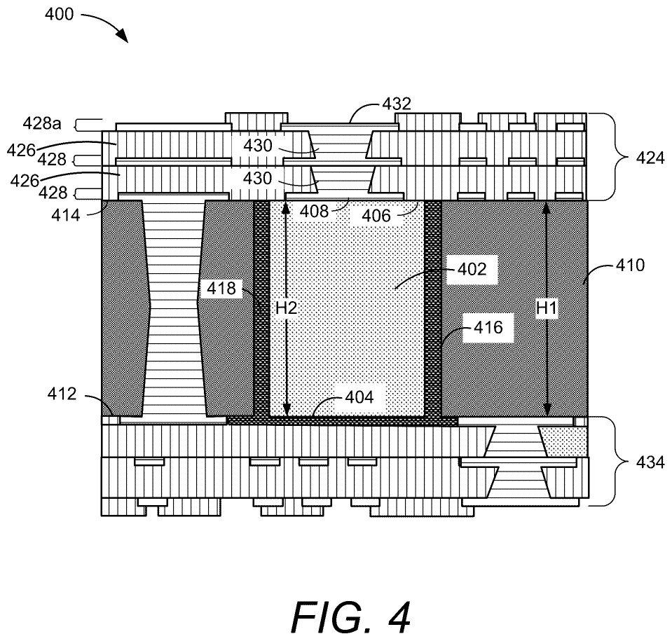

FIG. 4 is a cross-sectional of view of an example substrate 400, according to aspects of the disclosure. In this example, the substrate 400 includes an electronic component 402 having a lower planar surface 404 and an upper planar surface 406. The upper planar surface 406 of the electronic component 402 includes one or more electronic component terminals 408 providing an electrical connection with the electronic component 402.

The substrate 400 further includes a core 410 having a lower planar surface 412 and an upper planar surface 414. A cavity 416 extends through the core 410 between the upper planar surface 414 and lower planar surface 412. In this example, the thickness H1 of the core 410 is substantially the same dimension as the height H2 of the electronic component 402 as measured between the upper planar surface 406 and lower planar surface 404 of the electronic component 402. In accordance with various aspects of the disclosure, the core 410 may be a thin core having a thickness H1 that is less than or equal to 800 micrometers. Alternatively, the core may be a thick core having a thickness H1 that is greater than 700 micrometers (e.g., above 760 micrometers). In this example, the electronic component 402 occupies a substantial volume (e.g., 66%) of the cavity 416. In accordance with various aspects of the disclosure, the electronic component 402 is fixed within the cavity 416 with a cured hole-plugging ink 418. In an aspect, the cured hole-plugging ink 418 is initially deposited as a liquid hole-plugging ink that surrounds the electronic component 402 and fills the cavity 416 without the voids typically associated with fills formed from commonly used dielectric resins. Once the liquid hole-plugging ink is deposited, the liquid hole-plugging ink is subjected to a curing process to form the cured hole-plugging ink 418 as a substantially void-free solid material (e.g., having no voids, or having fewer voids and/or voids of smaller dimensions than the voids typically found in conventional dielectric fills used to embed electronic components under similar geometric filling constraints) thereby providing a robust mounting of the electronic component 402 in the cavity 416. In this example, the hole-plugging ink 418 extends to cover the lower planar surface 404 of the electronic component 402 as well as a portion of the lower planar surface 412 of the core 410. Since the hole-plugging ink 418 is substantially free of the types and numbers of voids typically associated with more common dielectric material fills, the electronic component 402 is robustly secured within the cavity 416 in a manner that limits the chances that the electronic component 402 will delaminate from the core 410.

In an aspect, the substrate 400 may include an upper metallization structure 424 disposed over the upper planar surface 414 of the core 410. In the example shown in FIG. 4, the upper metallization structure 424 includes one or more dielectric layers 426, one or more patterned metallization layers 428, and one or more vias 430. In an aspect, the upper metallization structure 424 is configured to provide one or more conductive paths between one or more terminals 432 of an uppermost metallization layer 428a and the one or more electronic component terminals 408. A lower metallization structure 434 may also be disposed over the lower planar surface 412 of the core 410.

Although the dielectric layers 426 are shown in FIG. 4 as separate layers, it will be understood that multiple dielectric layers may be fused during the manufacturing process so as to appear and function as a single dielectric structure. Further, it will be understood that different layers of the dielectric layers 426 may be formed from different dielectric materials during the manufacturing process. In an aspect, different dielectric materials for the different dielectric layers may be used when one or more of the dielectric layers 426 are to have a different dielectric constant than another of the dielectric layers 426.

As noted, the cavity 416 may be filled with the hole-plugging ink 418 to secure the electronic component 402 within the cavity 416. In an aspect, the hole-plugging ink 418 may completely fill the cavity 416 so that the entirety of the electronic component 402 is enclosed by the hole-plugging ink 418.

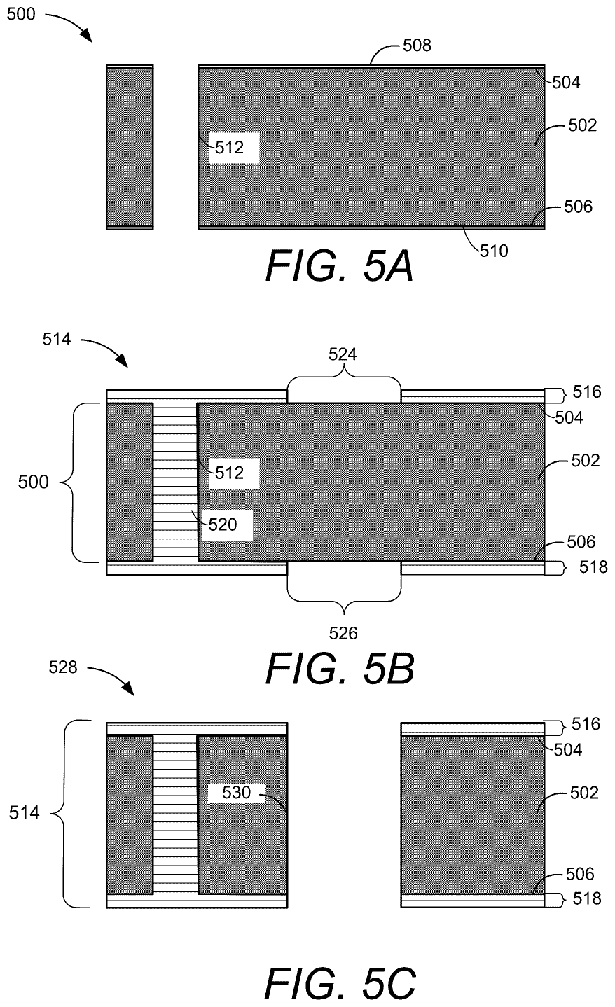

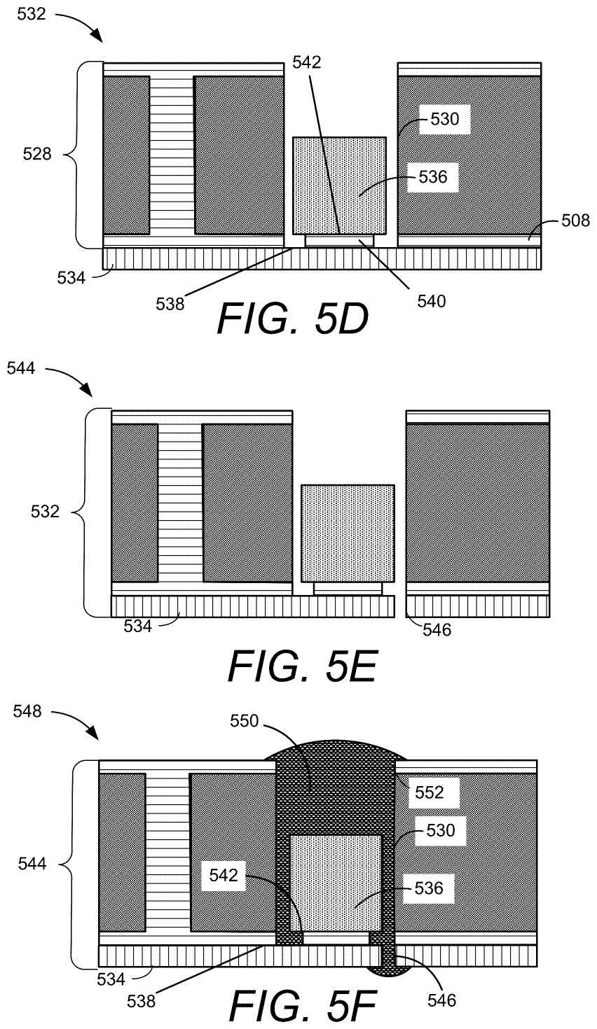

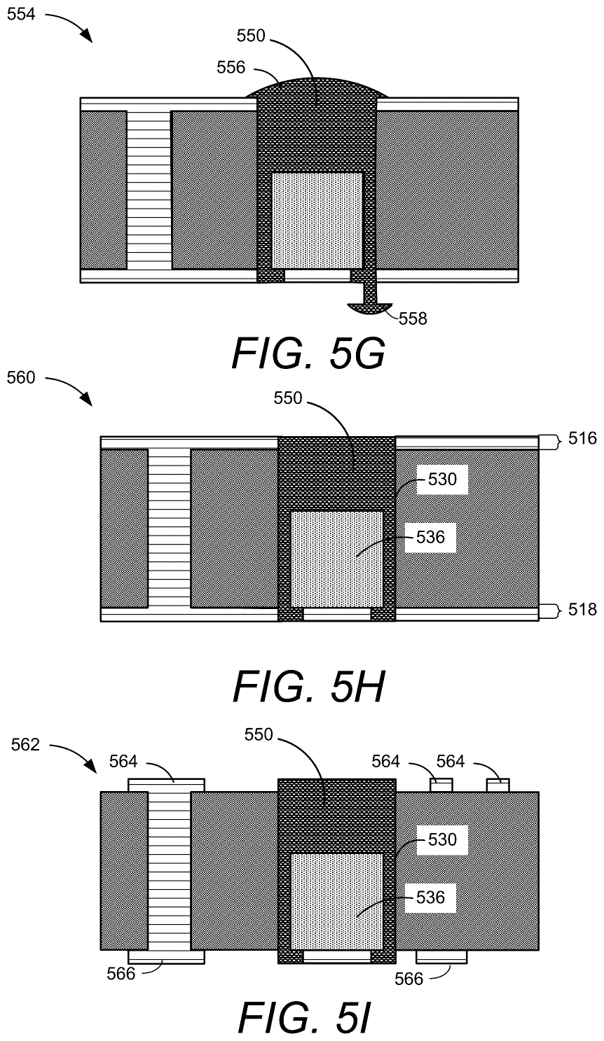

FIGS. 5A through 5I illustrate example operations that may be performed during the fabrication of an example substrate, according to aspects of the disclosure. FIG. 5A shows a first intermediate state 500 of the substrate during the example fabrication process, according to aspects of the disclosure. In this example, the first intermediate state 500 of the substrate includes a core 502 with an upper planar surface 504 and a lower planar surface 506. A thin metal cladding layer 508 is disposed over the upper planar surface 504. A further thin metal cladding layer 510 is disposed over the lower planar surface 506. The first intermediate state 500 of the substrate also includes a via structure 512 extending between the upper planar surface 504 and the lower planar surface 506 of the core 502. In an aspect, the core 502 is subject to a drilling operation to form the via structure 512.

FIG. 5B shows a second intermediate state 514 of the substrate during the example fabrication process, according to aspects of the disclosure. In this example, a metallization layer 516 is formed over the thin metal cladding layer 508 at the upper planar surface 504 of the core 502 and a further metallization layer 518 is formed over the thin metal cladding layer 510 at the lower planar surface 506 of the core 502. The via structure 512 has been at least partially filled to form a via 520 that electrically connects the metallization layers 516, 518. Depending on the thickness of the core 502, the via may be completely filled (as shown in FIG. 5B) or may be partially filled with metal leaving a central hollow portion of the via 520 that is not filled with metal (not shown in FIG. 5B). Region 524 at the upper planar surface 504 of the core 502 and region 526 at the lower planar surface 506 of the core 502 are exposed and not covered by the metallization layers 516 and 518. As will be understood, regions 524 and 526 may be formed in either an additive or subtractive metallization process.

FIG. 5C shows a third intermediate state 528 of the substrate during the example fabrication process, according to aspects of the disclosure. Here, the second intermediate state 514 of the substrate is processed (e.g., laser drilled) to form a cavity 530 in the core 502. In this example, the cavity 530 extends between the upper planar surface 504 of the core 502 and the lower planar surface 506 of the core 502.

FIG. 5D shows a fourth intermediate state 532 of the substrate during the example fabrication process, according to aspects of the disclosure. Here, a layer of a polyimide (PI) tape 534 is placed over the metallization layer 518 and over the lower opening of the cavity 530. An electronic component 536 is placed in the cavity 530 and mounted on an upper planar surface 538 of the PI tape 534 so that one or more electronic component terminals 540 at a lower planar surface 542 of the electronic component 536 are in contact with the upper planar surface 538 of the PI tape 534. In an aspect, the one or more electronic component terminals 540 provide an electrical connection with an electrical component (e.g., a deep trench capacitor) formed by or in the electronic component 536.

FIG. 5E shows a fifth intermediate state 544 of the substrate during the example fabrication process, according to aspects of the disclosure. Here, a vent 546 is formed through the PI tape 534 at the lower opening of the cavity 530.

FIG. 5F shows a sixth intermediate state 548 of the substrate during the example fabrication process, according to aspects of the disclosure. Here, a hole-plugging ink 550 is dispensed in an uncured state into the upper opening 552 of the cavity 530 and drawn downward through the cavity 530 through the vent 546. In an aspect, the hole-plugging ink 550 is drawn into the cavity 530 by a pressure differential created between the upper opening 552 and the vent 546. In this example, the hole-plugging ink 550 completely fills the cavity 530 including all regions between the sidewalls of the electronic component 536 and sidewalls of the cavity 530. In an aspect, the hole-plugging ink 550 also fills the region between the lower planar surface 542 of the electronic component 536 and the upper planar surface 538 of the PI tape 534. A residual amount of the hole-plugging ink 550 extends beyond the cavity 530 into areas above the upper opening 552 of the cavity 530 and over the PI tape 534 near the vent 546. In an aspect, the hole-plugging ink 550 is subject to a pre-curing process while in the sixth intermediate state 548.

FIG. 5G shows a sixth intermediate state 554 of the substrate during the example fabrication process, according to aspects of the disclosure. Here, the layer of PI tape 534 is removed. According to certain aspects of the disclosure, the hole-plugging ink 550 is then subject to a curing process (e.g., a thermal curing process, an ultraviolet light curing process, etc.). Once cured, the hole-plugging ink 550 forms a solid structure in which the electronic component 536 is embedded and secured within the cavity 530. In an aspect, the cavity 530 is completely filled with the uncured hole-plugging ink 550 so that the hole-plugging ink 550 cures to form a structure that is substantially free of voids (e.g., having no voids, or having fewer voids and/or voids of smaller dimensions than the voids typically found in conventional dielectric fills used to embed electronic components under similar geometric filling constraints) thereby providing a robust mounting of the electronic component 536 in the cavity 530.

The curing of the hole-plugging ink 550 and removal of the layer of PI tape 534 leaves flashing 556, 558 that is removed (e.g., using a brushing process) to form the seventh intermediate state 560 of the substrate shown in FIG. 5H. In the example shown in FIG. 5H, the flashing 556 is removed so that the cured hole-plugging ink 550 is a level with the upper surface of the metallization layer 516. Similarly, the flashing 558 is removed so that the cured hole-plugging ink 550 is level with the lower surface of metallization layer 518.

FIG. 5I shows an eighth intermediate state 562 of the substrate during the example fabrication process, according to aspects of the disclosure. Here, portions of the metallization layers 516 and 518 are selectively removed to form a first set of conductive traces 564 at the upper planar surface 504 of the core 502 and a second set of conductive traces 566 at the lower planar surface 506 of the core 502. In an aspect, the eighth intermediate state 562 of the substrate fabrication process may be subject to multiple build-upper layers of dielectric and metal materials to ultimately form an upper metallization structure (see, e.g., FIG. 4) of the substrate.

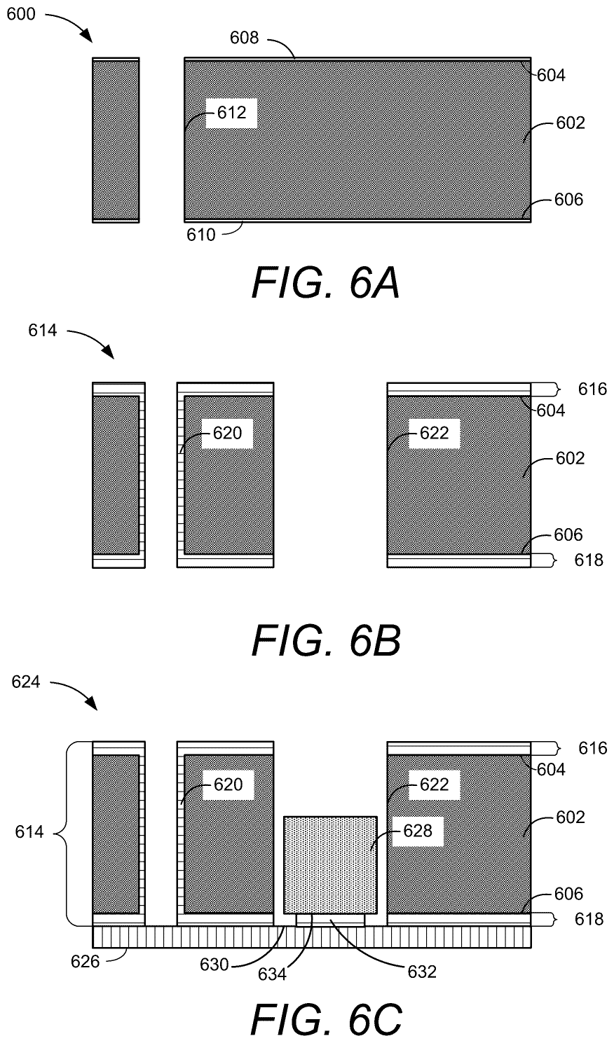

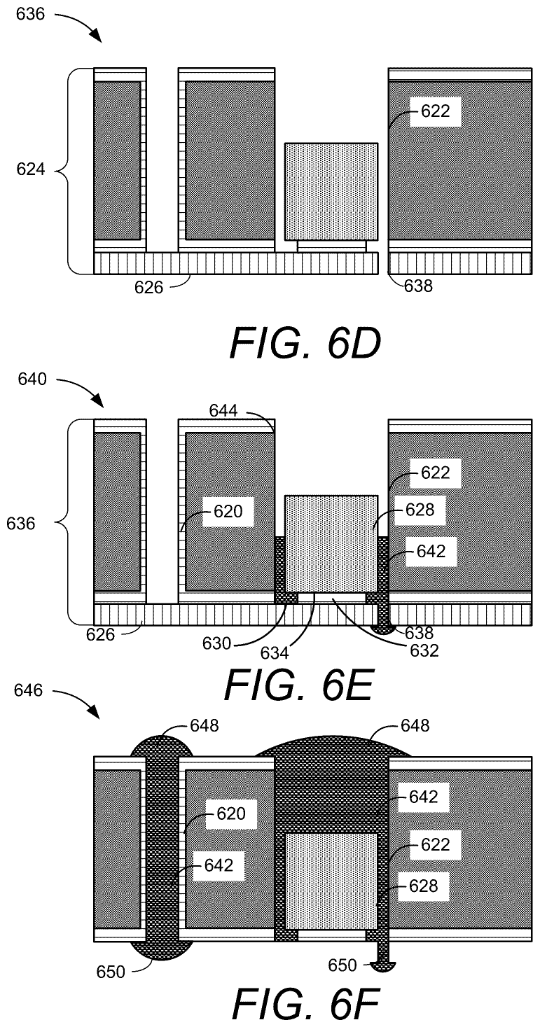

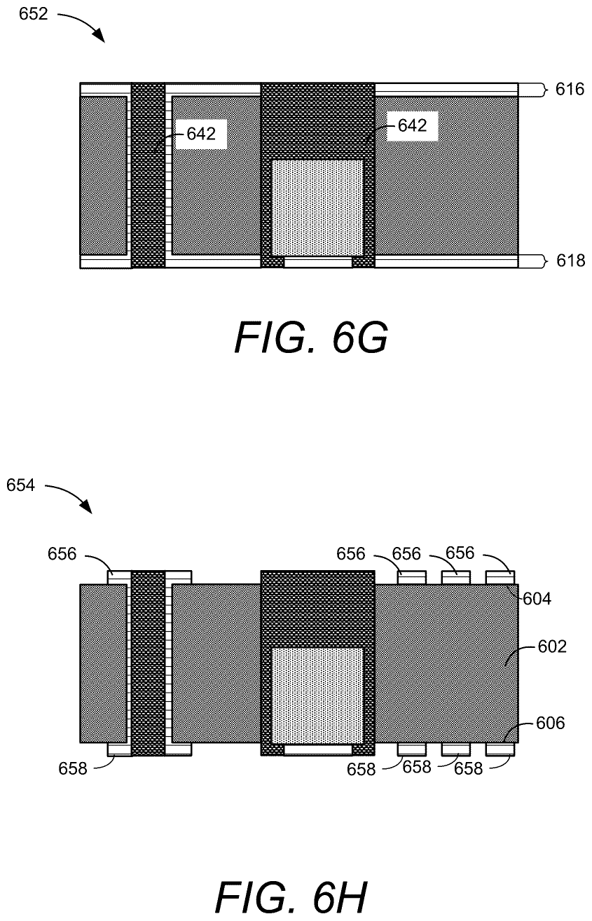

FIGS. 6A through 6H illustrate another set of example operations performed during the fabrication of an example substrate, according to aspects of the disclosure. FIG. 6A shows a first intermediate state 600 of the substrate during the example fabrication process, according to aspects of the disclosure. In this example, the first intermediate state 600 of the substrate includes a core 602 with an upper planar surface 604 and a lower planar surface 606. A thin metal cladding layer 608 is disposed over the upper planar surface 604. A further thin metal cladding layer 610 is disposed over the lower planar surface 606. The first intermediate state 600 of the substrate also includes a via structure 612 extending between the upper planar surface 604 and the lower planar surface 606 of the core 602. In an aspect, the core 602 is subject to a drilling operation to form the via structure 612.

FIG. 6B shows a second intermediate state 614 of the substrate during the example fabrication process, according to aspects of the disclosure. In this example, a metallization layer 616 is formed over the thin metal cladding layer 608 at the upper planar surface 604 of the core 602 and a further metallization layer 618 is formed over the thin metal cladding layer 610 at the lower planar surface 606 of the core 602. The via structure 612 has been partially filled to form a hollow via 620 that electrically connects the metallization layers 616, 618. The second intermediate state 614 of the substrate also includes a cavity 622 (e.g., laser drilled) in the core 602. In this example, the cavity 622 extends between the upper planar surface 604 of the core 602 and the lower planar surface 606 of the core 602.

FIG. 6C shows a third intermediate state 624 of the substrate during the example fabrication process, according to aspects of the disclosure. Here, a layer of a PI tape 626 is placed over the metallization layer 618 and over the lower opening of the cavity 622. An electronic component 628 is placed in the cavity 622 and mounted on an upper planar surface 630 of the PI tape 626 so that one or more electronic component terminals 632 at a lower planar surface 634 of the electronic component 628 are in contact with the upper planar surface 630 of the PI tape 626. In an aspect, the one or more electronic component terminals 632 provide an electrical connection with an electrical component (e.g., a deep trench capacitor) formed by or in the electronic component 628.

FIG. 6D shows a fourth intermediate state 636 of the substrate during the example fabrication process, according to aspects of the disclosure. Here, a vent 638 is formed through the PI tape 626 at the lower opening of the cavity 622.

FIG. 6E shows a fifth intermediate state 640 of the substrate during the example fabrication process, according to aspects of the disclosure. Here, a hole-plugging ink 642 is dispensed in an uncured state into the upper opening 644 of the cavity 622 and drawn downward through the cavity 622 and through the vent 638. In an aspect, the hole-plugging ink 642 is drawn into the cavity 622 by a pressure differential created between the upper opening 644 of the cavity 622 and the vent 638. Unlike the process shown in FIG. 6F, in this example, the uncured hole-plugging ink 642 only partially fills the cavity 622 including only a portion of the regions between the sidewalls of the electronic component 628 and sidewalls of the cavity 622. In an aspect, the hole-plugging ink 642 also fills the region between the lower planar surface 634 of the electronic component 628 and the upper planar surface 630 of the PI tape 626. A residual amount of the hole-plugging ink 642 extends beyond the cavity 622 into an area over the PI tape 626 near the vent 638. In accordance with certain aspects of the disclosure, the hole-plugging ink 642 may be subject to a pre-curing process at this point in the fabrication process. In an aspect, none of the hole-plugging ink 642 is allowed to enter the hollow via 620. To this end, the hollow via 620 may be temporarily protected with an overlying barrier that is subsequently removed after the partial amount of the hole-plugging ink 642 is deposited in the cavity 622.

FIG. 6F shows a sixth intermediate state 646 of the substrate during the example fabrication process, according to aspects of the disclosure. Here, the layer of PI tape 626 is removed. In an aspect, the remaining unfilled portion of the cavity 622 is now filled with a further amount of hole-plugging ink 642 in its uncured state. In an aspect, the hollow via 620 is also filled with the hole-plugging ink 642 in an uncured state. In accordance with certain aspects of the disclosure, the hollow via 620 may be filled with the hole-plugging ink 642 at the same time that the remaining unfilled portions of the cavity 622 are filled with the hole-plugging ink 642.

The hole-plugging ink 642 in the hollow via 620 and the cavity 622 may then be subject to a curing process. Once cured, the hole-plugging ink 642 forms a solid structure in which the electronic component 628 is embedded for securement within the cavity 622. The curing of the hole-plugging ink 642 and removal of the layer of PI tape 626 leaves flashing 648, 650 that is removed (e.g., using a brushing process) to form the seventh intermediate state 652 of the substrate shown in FIG. 6G. In the example shown in FIG. 6G, the flashing 648 is removed so that the cured hole-plugging ink 642 is a level with the upper surface of the metallization layer 616. Similarly, the flashing 650 is removed so that the cured hole-plugging ink 642 is level with the lower surface of metallization layer 618.

FIG. 6H shows an eighth intermediate state 654 of the substrate during the example fabrication process, according to aspects of the disclosure. Here, portions of the metallization layers 616 and 618 are selectively removed to form a first set of conductive traces 656 at the upper planar surface 604 of the core 602 and a second set of conductive traces 658 at the lower planar surface 606 of the core 602. In an aspect, the eighth intermediate state 654 of the substrate fabrication process may be subject to multiple build-upper layers of dielectric and metal materials to may be subject to multiple build-upper layers to form the upper metallization structure (see, e.g., FIG. 4) of the substrate.

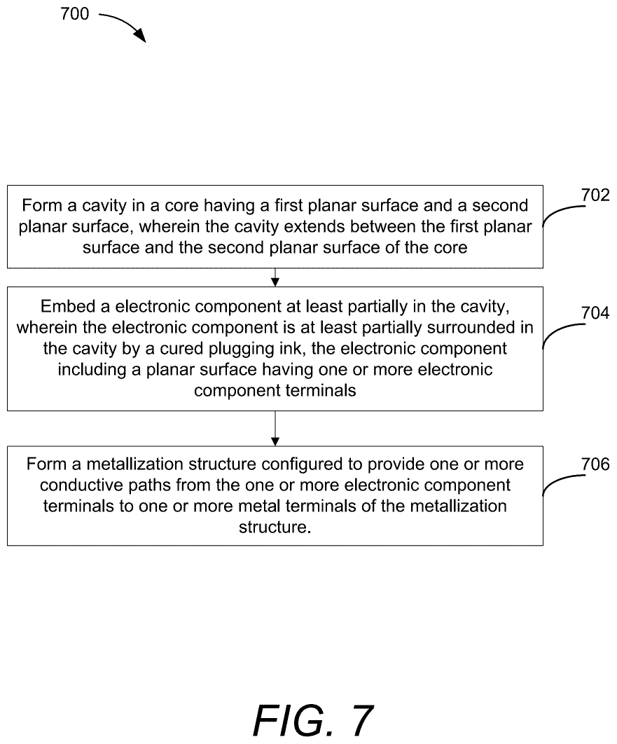

FIG. 7 is a flowchart showing an example method 700 for fabricating a substrate, according to aspects of the disclosure. At operation 702, a cavity is formed in a core having a first planar surface and a second planar surface, wherein the cavity extends between the first planar surface and the second planar surface of the core. At operation 704, an electronic component is embedded at least partially in the cavity, wherein the electronic component is at least partially surrounded in the cavity by a cured plugging ink, the electronic component including a planar surface having one or more electronic component terminals. At operation 706, a metallization structure is formed and configured to provide one or more conductive paths from the one or more electronic component terminals to one or more metal terminals of the metallization structure.

In some aspects, embedding the electronic component at least partially in the cavity comprises: covering a lower opening of the cavity with a polyimide (PI) tape; and inserting the electronic component into the cavity so that the one or more electronic component terminals at the planar surface of the electronic component are in contact with an upper surface of the PI tape.

In some aspects, embedding the electronic component at least partially in the cavity further comprises: forming a vent through the PI tape at the lower opening of the cavity; filling the cavity to surround the electronic component with an uncured plugging ink; pre-curing the uncured plugging ink in the cavity to provide a pre-cured plugging ink in the cavity; detaching the PI tape; and curing the pre-cured plugging ink to provide the cured plugging ink mounting the electronic component in the cavity.

In some aspects, filling the cavity to surround the electronic component with the uncured plugging ink comprises: dispensing the uncured plugging ink through an upper opening of the cavity; and providing a pressure differential between the upper opening of the cavity and the vent to draw the uncured plugging ink into the cavity.

In some aspects, the method includes removing excess cured plugging ink material from an upper portion of the cavity and a lower portion of the cavity using a brushing operation.

In some aspects, embedding the electronic component at least partially in the cavity further comprises: forming a vent through the PI tape at a lower opening of the cavity; filling the cavity with a first amount of an uncured plugging ink, wherein the first amount of the uncured plugging ink only partially surrounds the electronic component; pre-curing the first amount of the uncured plugging ink in the cavity; detaching the PI tape; filling the cavity with a second amount of the uncured plugging ink, wherein the second amount of the uncured plugging ink completes filling of the cavity to surround the electronic component; and curing the pre-cured plugging ink and the uncured plugging ink to form the cured plugging ink that at least partially surrounds the electronic component in the cavity.

In some aspects, the method includes filling a hollow portion of at least one metal via structure extending through the core with the uncured plugging ink, wherein the hollow portion of the at least one metal via structure is filled with the uncured plugging ink in a plugging ink filling process concurrent with the filling of the cavity with the second amount of the uncured plugging ink.

In some aspects, the electronic component comprises a deep trench capacitor.

A technical advantage of the method 700 is that it may be used to form a substrate with an embedded electronic component (e.g., deep trench capacitor) in which the embedded electronic component is robustly mounted in a cavity of the substrate. The robustness of the mount is not as dependent on the size of the electronic component or the thickness of the core as electronic component embedding processes using conventional cavity fills.

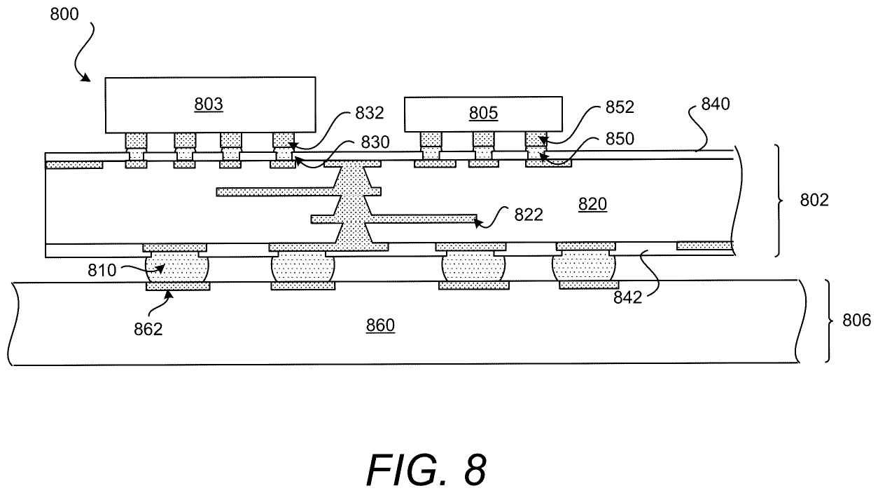

FIG. 8 illustrates a profile view of a package 800 that includes a surface mount substrate 802, an integrated device 803, and an integrated passive device 805 (e.g., a substrate having an embedded electronic component in a core), according to aspects of the disclosure. The package 800 may be coupled to a printed circuit board (PCB) 806 through a plurality of solder interconnects 810. The PCB 806 may include at least one board dielectric layer 860 and a plurality of board interconnects 862.

The surface mount substrate 802 includes at least one dielectric layer 820 (e.g., substrate dielectric layer), a plurality of interconnects 822 (e.g., substrate interconnects), a solder resist layer 840 and a solder resist layer 842. The integrated device 803 may be coupled to the surface mount substrate 802 through a plurality of solder interconnects 830. The integrated device 803 may be coupled to the surface mount substrate 802 through a plurality of pillar interconnects 832 and the plurality of solder interconnects 830. The integrated passive device 805 may be coupled to the surface mount substrate 802 through a plurality of solder interconnects 850. The integrated passive device 805 may be coupled to the surface mount substrate 802 through a plurality of pillar interconnects 852 and the plurality of solder interconnects 850.

The package (e.g., 800) may be implemented in a radio frequency (RF) package. The RF package may be a radio frequency front end (RFFE) package. A package (e.g., 800) may be configured to provide Wireless Fidelity (WiFi) communication and/or cellular communication (e.g., 2G, 3G, 4G, 5G). The package (e.g., 800.) may be configured to support Global System for Mobile (GSM) Communications, Universal Mobile Telecommunications System (UMTS), and/or Long-Term Evolution (LTE). The package (e.g., 800) may be configured to transmit and receive signals having different frequencies and/or communication protocols.

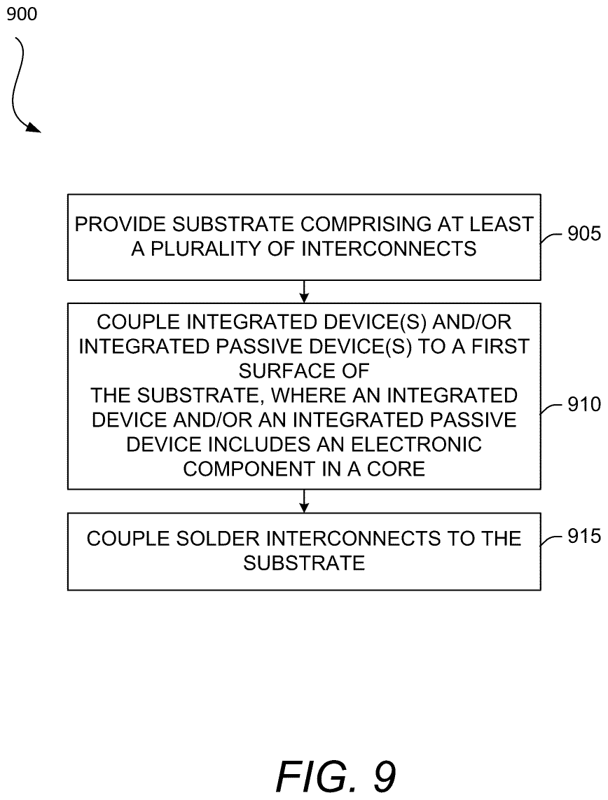

FIG. 9 illustrates an example method 900 for providing or fabricating a package that includes an integrated device comprising a package substrate having an electronic component in a core, according to aspects of the disclosure. In some implementations, the method 900 of FIG. 9 may be used to provide or fabricate the package 800 of FIG. 8 described in the disclosure. However, the method 900 may be used to provide or fabricate any of the packages described in the disclosure.

It should be noted that the method of FIG. 9 may combine one or more processes in order to simplify and/or clarify the method for providing or fabricating a package that includes an integrated device comprising a package substrate. In some implementations, the order of the processes may be changed or modified.

The method provides (at 905) a substrate (e.g., 802). The substrate 802 may be provided by a supplier or fabricated. The substrate 802 includes at least one dielectric layer 820, and a plurality of interconnects 822. The substrate 802 may include an embedded trace substrate (ETS). In some implementations, the at least one dielectric layer 820 may include prepreg layers.

The method couples (at 910) at least one integrated device (e.g., 803) to the first surface of the substrate (e.g., 802). For example, the integrated device 803 may be coupled to the substrate 802 through the plurality of pillar interconnects 832 and the plurality of solder interconnects 830. The plurality of pillar interconnects 832 may be optional. The plurality of solder interconnects 830 are coupled to the plurality of interconnects 822. A solder reflow process may be used to couple the integrated device 803 to the plurality of interconnects through the plurality of solder interconnects 830.

The method also couples (at 910) at least one integrated passive device (e.g., 805) to the first surface of the substrate (e.g., 802). For example, the integrated passive device 805 may be coupled to the substrate 802 through the plurality of pillar interconnects 852 and the plurality of solder interconnects 850. The plurality of pillar interconnects 852 may be optional. The plurality of solder interconnects 850 are coupled to the plurality of interconnects 822. A solder reflow process may be used to couple the integrated passive device 805 to the plurality of interconnects through the plurality of solder interconnects 850.

The method couples (at 915) a plurality of solder interconnects (e.g., 810) to the second surface of the substrate (e.g., 802). A solder reflow process may be used to couple the plurality of solder interconnects 810 to the substrate.

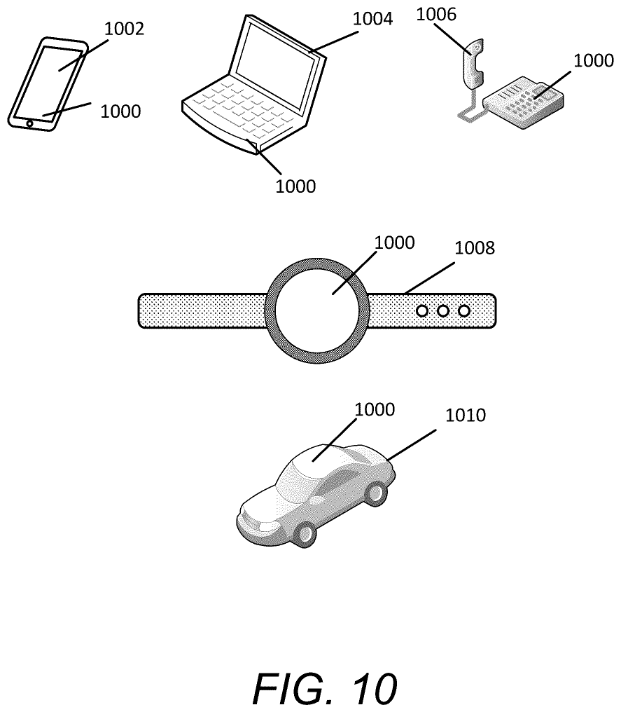

FIG. 10 illustrates various electronic devices that may be integrated with any of the aforementioned devices, integrated devices, integrated circuit (IC) packages, integrated circuit (IC) devices, semiconductor devices, integrated circuits, dies, interposer packages, package-on-package (POP), System in Package (SiP), or System on Chip (SoC). For example, a mobile phone device 1002, a laptop computer device 1004, a fixed location terminal device 1006, a wearable device 1008, or automotive vehicle 1010 may include a device 1000 as described herein. The device 1000 may be, for example, any of the devices and/or integrated circuit (IC) packages described herein. The devices 1002, 1004, 1006 and 1008 and the vehicle 1010 illustrated in FIG. 10 are merely exemplary. Other electronic devices may also feature the device 1000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

Implementation examples are described in the following numbered aspects:

Aspect 1. An electronic device, comprising: a substrate comprising a core having an upper planar surface and a lower planar surface, wherein the core includes a cavity extending between the upper planar surface of the core and the lower planar surface of the core; an electronic component at least partially disposed in the cavity, wherein the electronic component is at least partially surrounded in the cavity by a cured plugging ink, the electronic component including an upper planar surface having one or more electronic component terminals; and an upper metallization structure configured to provide one or more conductive paths from the one or more electronic component terminals to one or more upper metal terminals of the upper metallization structure.

Aspect 2. The electronic device of aspect 1, wherein: the electronic component occupies at least 66% of the cavity.

Aspect 3. The electronic device of any of aspects 1 to 2, wherein: the core includes a plurality of interior sidewalls defining the cavity; the electronic component includes a plurality of exterior sidewalls facing the plurality of interior sidewalls of the cavity; and the cured plugging ink fills regions between the plurality of exterior sidewalls of the electronic component and the plurality of interior sidewalls of the core.

Aspect 4. The electronic device of any of aspects 1 to 3, further comprising: a lower dielectric layer disposed over the lower planar surface of the core and below a lower planar surface of the electronic component, wherein the cured plugging ink fills a region between a lower planar surface of the electronic component and the lower dielectric layer.

Aspect 5. The electronic device of any of aspects 1 to 4, further comprising: one or more metal vias extending between the upper planar surface of the core and the lower planar surface of the core.

Aspect 6. The electronic device of aspect 5, wherein: the core has a thickness equal to or less than 800 micrometers.

Aspect 7. The electronic device of any of aspects 5 to 6, wherein: at least one metal via of the of the one or more metal vias includes a metal via structure having a hollow cavity, wherein the hollow cavity of the metal via structure is filled with the cured plugging ink.

Aspect 8. The electronic device of aspect 7, wherein: the core has a thickness above 800 micrometers.

Aspect 9. The electronic device of any of aspects 1 to 8, further comprising: an electronic circuit package mounted at the one or more upper metal terminals of the upper metallization structure.

Aspect 10. The electronic device of any of aspects 1 to 9, wherein: the electronic component comprises a deep trench capacitor.

Aspect 11. The electronic device of any of aspects 1 to 10, wherein the electronic device comprises at least one of: a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Aspect 12. A substrate, comprising: a core having an upper planar surface and a lower planar surface, wherein the core includes a cavity extending between the upper planar surface of the core and the lower planar surface of the core; an electronic component at least partially disposed in the cavity, wherein the electronic component is at least partially surrounded in the cavity by a cured plugging ink, the electronic component including an upper planar surface having one or more electronic component terminals; and an upper metallization structure configured to provide one or more conductive paths from the one or more electronic component terminals to one or more upper metal terminals of the upper metallization structure.

Aspect 13. The substrate of aspect 12, wherein: the electronic component occupies at least 66% of the cavity.

Aspect 14. The substrate of any of aspects 12 to 13, wherein: the core includes a plurality of interior sidewalls defining the cavity; the electronic component includes a plurality of exterior sidewalls facing the plurality of interior sidewalls of the cavity; and the cured plugging ink fills regions between the plurality of exterior sidewalls of the electronic component and the plurality of interior sidewalls of the core.

Aspect 15. The substrate of any of aspects 12 to 14, further comprising: a lower dielectric layer disposed over the lower planar surface of the core and below a lower planar surface of the electronic component, wherein the cured plugging ink fills a region between a lower planar surface of the electronic component and the lower dielectric layer.

Aspect 16. The substrate of any of aspects 12 to 15, comprising: one or more metal vias extending between the upper planar surface of the core and the lower planar surface of the core.

Aspect 17. The substrate of aspect 16, wherein: at least one metal of the of the one or more metal vias includes a metal via structure having a hollow cavity, wherein the hollow cavity of the metal via structure is filled with the cured plugging ink.

Aspect 18. The substrate of aspect 17, wherein: the core has a thickness above 700 micrometers.

Aspect 19. The substrate of any of aspects 12 to 18, further comprising: an electronic circuit package mounted at the one or more upper metal terminals of the upper metallization structure.

Aspect 20. The substrate of any of aspects 12 to 19, wherein: the electronic component comprises a deep trench capacitor.

Aspect 21. A method for fabricating a substrate, comprising: forming a cavity in a core having a first planar surface and a second planar surface, wherein the cavity extends between the first planar surface and the second planar surface of the core; embedding an electronic component at least partially in the cavity, wherein the electronic component is at least partially surrounded in the cavity by a cured plugging ink, the electronic component including a planar surface having one or more electronic component terminals; and forming a metallization structure configured to provide one or more conductive paths from the one or more electronic component terminals to one or more metal terminals of the metallization structure.

Aspect 22. The method of aspect 21, wherein embedding the electronic component at least partially in the cavity comprises: covering a lower opening of the cavity with a polyimide (PI) tape; and inserting the electronic component into the cavity so that the one or more electronic component terminals at the planar surface of the electronic component are in contact with an upper surface of the PI tape.

Aspect 23. The method of aspect 22, wherein embedding the electronic component at least partially in the cavity further comprises: forming a vent through the PI tape at the lower opening of the cavity; filling the cavity to surround the electronic component with an uncured plugging ink; pre-curing the uncured plugging ink in the cavity to provide a pre-cured plugging ink in the cavity; detaching the PI tape; and curing the pre-cured plugging ink to provide the cured plugging ink mounting the electronic component in the cavity.

Aspect 24. The method of aspect 23, wherein filling the cavity to surround the electronic component with the uncured plugging ink comprises: dispensing the uncured plugging ink through an upper opening of the cavity; and providing a pressure differential between the upper opening of the cavity and the vent to draw the uncured plugging ink into the cavity.

Aspect 25. The method of any of aspects 23 to 24, further comprising: removing excess cured plugging ink material from an upper portion of the cavity and a lower portion of the cavity using a brushing operation.

Aspect 26. The method of any of aspects 22 to 25, wherein embedding the electronic component at least partially in the cavity further comprises: forming a vent through the PI tape at a lower opening of the cavity; filling the cavity with a first amount of an uncured plugging ink, wherein the first amount of the uncured plugging ink only partially surrounds the electronic component; pre-curing the first amount of the uncured plugging ink in the cavity; detaching the PI tape; filling the cavity with a second amount of the uncured plugging ink, wherein the second amount of the uncured plugging ink completes filling of the cavity to surround the electronic component; and curing the pre-cured plugging ink and the uncured plugging ink to form the cured plugging ink that at least partially surrounds the electronic component in the cavity.

Aspect 27. The method of aspect 26, further comprising: filling a hollow portion of at least one metal via structure extending through the core with the uncured plugging ink, wherein the hollow portion of the at least one metal via structure is filled with the uncured plugging ink in a plugging ink filling process concurrent with the filling of the cavity with the second amount of the uncured plugging ink.

Aspect 28. The method of any of aspects 21 to 27, wherein: the electronic component comprises a deep trench capacitor.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

It is noted that the figures in the disclosure may represent actual representations and/or conceptual representations of various parts, components, objects, devices, packages, integrated devices, integrated circuits, and/or transistors. In some instances, the figures may not be to scale. In some instances, for the purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. The terms “top” and “bottom” are arbitrary. A component that is located on top may be located over a component that is located on the bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the detailed description above, it can be seen that different features are grouped together in examples. This manner of disclosure should not be understood as an intention that the example aspects have more features than are explicitly mentioned in each aspect. Rather, the various aspects of the disclosure may include fewer than all features of an individual example aspect disclosed. Therefore, the following aspects should hereby be deemed to be incorporated in the description, wherein each aspect by itself can stand as a separate example. Although each dependent aspect can refer in the aspects to a specific combination with one of the other aspects, the aspect(s) of that dependent aspect are not limited to the specific combination. It will be appreciated that other example aspects can also include a combination of the dependent aspect(s) with the subject matter of any other dependent aspect or independent aspect or a combination of any feature with other dependent and independent aspects. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of an aspect can be included in any other independent aspect, even if the aspect is not directly dependent on the independent aspect.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An electronic device, comprising:
a substrate comprising:
a core having an upper planar surface and a lower planar surface, wherein the core includes a cavity extending between the upper planar surface of the core and the lower planar surface of the core;
an electronic component at least partially disposed in the cavity, wherein the electronic component is at least partially surrounded in the cavity by a cured plugging ink, the electronic component including an upper planar surface having one or more electronic component terminals; and
an upper metallization structure configured to provide one or more conductive paths from the one or more electronic component terminals to one or more upper metal terminals of the upper metallization structure.

2. The electronic device of claim 1, wherein:
the electronic component occupies at least 66% of the cavity.

3. The electronic device of claim 1, wherein:
the core includes a plurality of interior sidewalls defining the cavity;
the electronic component includes a plurality of exterior sidewalls facing the plurality of interior sidewalls of the cavity; and
the cured plugging ink fills regions between the plurality of exterior sidewalls of the electronic component and the plurality of interior sidewalls of the core.

4. The electronic device of claim 1, further comprising:
a lower dielectric layer disposed over the lower planar surface of the core and below a lower planar surface of the electronic component, wherein the cured plugging ink fills a region between a lower planar surface of the electronic component and the lower dielectric layer.

5. The electronic device of claim 1, further comprising:
one or more metal vias extending between the upper planar surface of the core and the lower planar surface of the core.

6. The electronic device of claim 5, wherein:
the core has a thickness equal to or less than 800 micrometers.

7. The electronic device of claim 5, wherein:
at least one metal via of the of the one or more metal vias includes a metal via structure having a hollow cavity, wherein the hollow cavity of the metal via structure is filled with the cured plugging ink.

8. The electronic device of claim 7, wherein:
the core has a thickness above 800 micrometers.

9. The electronic device of claim 1, further comprising:
an electronic circuit package mounted at the one or more upper metal terminals of the upper metallization structure.

10. The electronic device of claim 1, wherein:
the electronic component comprises a deep trench capacitor.

11. The electronic device of claim 1, wherein the electronic device comprises at least one of:
a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

12. A substrate, comprising:
a core having an upper planar surface and a lower planar surface, wherein the core includes a cavity extending between the upper planar surface of the core and the lower planar surface of the core;
an electronic component at least partially disposed in the cavity, wherein the electronic component is at least partially surrounded in the cavity by a cured plugging ink, the electronic component including an upper planar surface having one or more electronic component terminals; and
an upper metallization structure configured to provide one or more conductive paths from the one or more electronic component terminals to one or more upper metal terminals of the upper metallization structure.

13. The substrate of claim 12, wherein:
the electronic component occupies at least 66% of the cavity.

14. The substrate of claim 12, wherein:
the core includes a plurality of interior sidewalls defining the cavity;
the electronic component includes a plurality of exterior sidewalls facing the plurality of interior sidewalls of the cavity; and
the cured plugging ink fills regions between the plurality of exterior sidewalls of the electronic component and the plurality of interior sidewalls of the core.

15. The substrate of claim 12, further comprising:
a lower dielectric layer disposed over the lower planar surface of the core and below a lower planar surface of the electronic component, wherein the cured plugging ink fills a region between a lower planar surface of the electronic component and the lower dielectric layer.

16. The substrate of claim 12, wherein the upper metallization structure comprises:
one or more metal vias.

17. The substrate of claim 16, wherein:
at least one metal via of the of the one or more metal vias includes a metal via structure having a hollow cavity, wherein the hollow cavity of the metal via structure is filled with the cured plugging ink.

18. The substrate of claim 17, wherein:
the core has a thickness above 700 micrometers.

19. The substrate of claim 12, further comprising:
an electronic circuit package mounted at the one or more upper metal terminals of the upper metallization structure.

20. The substrate of claim 12, wherein:
the electronic component comprises a deep trench capacitor.

21. A method for fabricating a substrate, comprising:
forming a cavity in a core having a first planar surface and a second planar surface, wherein the cavity extends between the first planar surface and the second planar surface of the core;
embedding an electronic component at least partially in the cavity, wherein the electronic component is at least partially surrounded in the cavity by a cured plugging ink, the electronic component including a planar surface having one or more electronic component terminals; and
forming a metallization structure configured to provide one or more conductive paths from the one or more electronic component terminals to one or more metal terminals of the metallization structure.

22. The method of claim 21, wherein embedding the electronic component at least partially in the cavity comprises:
covering a lower opening of the cavity with a polyimide (PI) tape; and
inserting the electronic component into the cavity so that the one or more electronic component terminals at the planar surface of the electronic component are in contact with an upper surface of the PI tape.

23. The method of claim 22, wherein embedding the electronic component at least partially in the cavity further comprises:
forming a vent through the PI tape at the lower opening of the cavity;
filling the cavity to surround the electronic component with an uncured plugging ink;
pre-curing the uncured plugging ink in the cavity to provide a pre-cured plugging ink in the cavity;
detaching the PI tape; and
curing the pre-cured plugging ink to provide the cured plugging ink mounting the electronic component in the cavity.

24. The method of claim 23, wherein filling the cavity to surround the electronic component with the uncured plugging ink comprises:
dispensing the uncured plugging ink through an upper opening of the cavity; and
providing a pressure differential between the upper opening of the cavity and the vent to draw the uncured plugging ink into the cavity.

25. The method of claim 23, further comprising:
removing excess cured plugging ink material from an upper portion of the cavity and a lower portion of the cavity using a brushing operation.

26. The method of claim 22, wherein embedding the electronic component at least partially in the cavity further comprises:
forming a vent through the PI tape at a lower opening of the cavity;
filling the cavity with a first amount of an uncured plugging ink, wherein the first amount of the uncured plugging ink only partially surrounds the electronic component;
pre-curing the first amount of the uncured plugging ink in the cavity;
detaching the PI tape;
filling the cavity with a second amount of the uncured plugging ink, wherein the second amount of the uncured plugging ink completes filling of the cavity to surround the electronic component; and
curing the pre-cured plugging ink and the uncured plugging ink to form the cured plugging ink that at least partially surrounds the electronic component in the cavity.

27. The method of claim 26, further comprising:
filling a hollow portion of at least one metal via structure extending through the core with the uncured plugging ink, wherein the hollow portion of the at least one metal via structure is filled with the uncured plugging ink in a plugging ink filling process concurrent with the filling of the cavity with the second amount of the uncured plugging ink.

28. The method of claim 21, wherein:
the electronic component comprises a deep trench capacitor.
